(19) United States
(12) Patent Application Publication
(10) Pub. No.: US 2026/0219116 A1
(43) Pub. Date: Jul. 30, 2026

(54) MONITORING DEVICE, MONITORING METHOD, AND PROGRAM

(71) Applicant: MITSUBISHI HEAVY INDUSTRIES, LTD., Tokyo (JP)

(72) Inventor: Nobuhide Hara, Tokyo (JP)

(73) Assignee: MITSUBISHI HEAVY INDUSTRIES, LTD., Tokyo (JP)

(21) Appl. No.: 19/149,301

(22) PCT Filed: Sep. 4, 2023
(86) PCT No.: PCT/JP2023/032200

§ 371 Date: Jul. 18, 2025

(30) Foreign Application Priority Data
Mar. 27, 2023 (JP) 2023-049799

(51) Int. Cl. G01K 17/12; F24F 11/46; F24F 110/10; F24F 110/30; F24F 140/50; F24F 140/60; G01K 3/14; G06F 1/20; H05K 7/20

(52) U.S. Cl. CPC G01K 17/12; F24F 11/46; G01K 3/14; G06F 1/206; H05K 7/20145; H05K 7/20209; H05K 7/20381; H05K 7/20745; H05K 7/20827; H05K 7/20836; F24F 2110/10; F24F 2110/30; F24F 2140/50; F24F 2140/60; G01K 2003/145; G01K 2201/00

(57) ABSTRACT

A monitoring device includes: an air conditioner evaluation unit that evaluates air conditioner power of an air conditioner including an outdoor unit installed outside a data center and an indoor unit installed inside the data center based on an outside air temperature measured outside the data center and a suction temperature of the indoor unit; a heat removal amount evaluation unit that evaluates a heat removal amount of a rack storing at least one electronic device in the data center based on an intake temperature obtained by measuring a temperature of air taken into the rack, an exhaust temperature obtained by measuring a temperature of the air exhausted from the rack, and a flow velocity of the air; and an efficiency evaluation unit that evaluates power usage effectiveness of the air conditioner in the data center based on the air conditioner power and the heat removal amount.

### TECHNICAL FIELD

The present disclosure relates to a monitoring device, a monitoring method, and a program.

Priority is claimed on Japanese Patent Application No. 2023-049799 filed on Mar. 27, 2023, the content of which is incorporated herein by reference.

### BACKGROUND ART

In order to realize a decarbonized society, it is being considered to reduce power consumption in data centers as well (see, for example, PTL 1 and PTL 2).

### CITATION LIST

### Patent Literature

[PTL 1] PCT Japanese Translation Patent Publication No. 2011-505784
[PTL 2] Japanese Patent No. 5649646

### SUMMARY OF INVENTION

### Technical Problem

An example of an index indicating the energy efficiency of a data center is power usage effectiveness (PUE). PUE is an index obtained by dividing the power consumption of an entire data center by the power consumption of an electronic device such as a server. In recent years, there has been a demand to monitor and manage PUE in order to suppress an increase in power consumption in a data center.

An object of the present disclosure is to provide a monitoring device, a monitoring method, and a program capable of monitoring power usage effectiveness (PUE) of an air conditioner in data centers.

### Solution to Problem

According to one aspect of the present disclosure, there is provided a monitoring device including: an air conditioner evaluation unit that evaluates air conditioner power of an air conditioner including an outdoor unit installed outside a data center and an indoor unit installed inside the data center based on an outside air temperature measured outside the data center and a suction temperature of the indoor unit; a heat removal amount evaluation unit that evaluates a heat removal amount of a rack storing at least one electronic device in the data center based on an intake temperature obtained by measuring a temperature of air taken into the rack, an exhaust temperature obtained by measuring a temperature of the air exhausted from the rack, and a flow velocity of the air; and an efficiency evaluation unit that evaluates power usage effectiveness of the air conditioner in the data center based on the air conditioner power and the heat removal amount.

According to another aspect of the present disclosure, there is provided a monitoring method including: a step of evaluating air conditioner power of an air conditioner including an outdoor unit installed outside a data center and an indoor unit installed inside the data center based on an outside air temperature measured outside the data center and a suction temperature of the indoor unit; a step of evaluating a heat removal amount of a rack storing at least one electronic device in the data center based on an intake temperature obtained by measuring a temperature of air taken into the rack, an exhaust temperature obtained by measuring a temperature of the air exhausted from the rack, and a flow velocity of the air; and a step of evaluating power usage effectiveness of the air conditioner in the data center based on the air conditioner power and the heat removal amount.

According to another aspect of the present disclosure, there is provided a program causing a monitoring device to execute: a step of evaluating air conditioner power of an air conditioner including an outdoor unit installed outside a data center and an indoor unit installed inside the data center based on an outside air temperature measured outside the data center and a suction temperature of the indoor unit; a step of evaluating a heat removal amount of a rack storing at least one electronic device in the data center based on an intake temperature obtained by measuring a temperature of air taken into the rack, an exhaust temperature obtained by measuring a temperature of the air exhausted from the rack, and a flow velocity of the air; and a step of evaluating power usage effectiveness of the air conditioner in the data center based on the air conditioner power and the heat removal amount.

### Advantageous Effects of Invention

According to the above aspects, the power usage effectiveness (PUE) of the air conditioner in the data center can be monitored.

### BRIEF DESCRIPTION OF DRAWINGS

FIG. 1 is a diagram showing an overall configuration of a monitoring system according to a first embodiment.

FIG. 2 is a diagram showing an example of an inlet measurement point and an outlet measurement point according to the first embodiment.

FIG. 3 is a block diagram showing a functional configuration of a monitoring device according to the first embodiment.

FIG. 4 is a flowchart showing an example of processing performed by the monitoring device according to the first embodiment.

FIG. 5 is a diagram showing an example of an inlet measurement point and an outlet measurement point according to a second embodiment.

FIG. 6 is a diagram showing a configuration of an air conditioner and a rack according to a third embodiment.

FIG. 7 is a flowchart showing an example of processing performed by a monitoring device according to the third embodiment.

FIG. 8 is a diagram for describing functions of the monitoring device according to the third embodiment.

### DESCRIPTION OF EMBODIMENTS

### First Embodiment

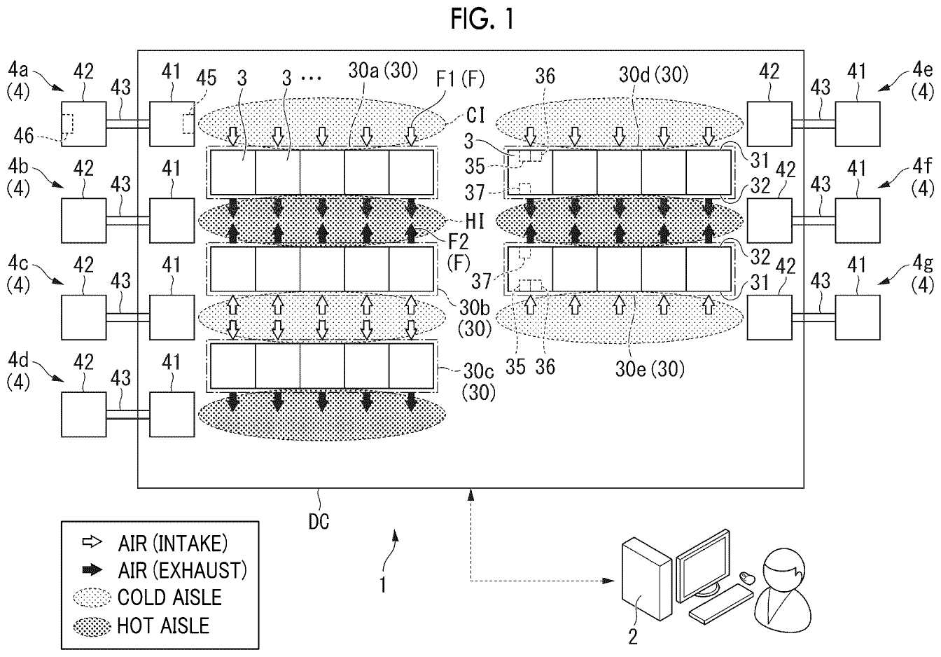

A first embodiment will be described below with reference to FIGS. 1 to 4.

### (Overall Configuration of Monitoring System)

FIG. 1 is a diagram showing an overall configuration of a monitoring system according to the first embodiment.

As shown in FIG. 1, a monitoring system 1 includes a monitoring device 2, a plurality of racks 3, and a plurality of air conditioners 4.

The monitoring device 2 is a system for monitoring the air conditioning and PUE of a data center DC. The detailed functional configuration of the monitoring device 2 will be described later.

The rack 3 (server rack) is installed in the data center DC and stores at least one electronic device therein. The electronic device is, for example, an information device such as a server or a router. It is assumed that each rack 3 has the same configuration.

An up-down direction on the paper surface is a front-rear direction of the rack 3, and a left-right direction on the paper surface is a left-right direction of the rack 3. In the example of FIG. 1, the plurality of racks 3 are aligned in the left-right direction to form a rack row 30. Furthermore, a plurality of rack rows 30 may be disposed at intervals in the front-rear direction and the left-right direction. In the example of FIG. 1, rack rows 30a, 30b, and 30c are disposed at intervals in the front-rear direction in the left side region, and rack rows 30d and 30e are disposed at intervals in the front-rear direction in the right side region.

The rack 3 has an air inlet on a front surface 31 for taking in cooling air F (intake air F1), and an air outlet on a rear surface 32 for exhausting the air F (exhaust air F2) whose temperature has increased after cooling electronic devices. The passages between the rack rows 30 arranged in the front-rear direction are disposed such that the front surfaces 31 (air inlets) or the rear surfaces 32 (air outlets) of the racks 3 face each other. In the example of FIG. 1, the rear surface 32 of the rack row 30a and the rear surface 32 of the rack row 30b are disposed to face each other. Furthermore, the front surface 31 of the rack row 30b and the front surface 31 of the rack row 30c are disposed to face each other. The passage to which the front surface 31 of the rack row 30 faces is a cold aisle CI, and the passage to which the rear surface 32 faces is a hot aisle HI.

An intake temperature sensor 35 and a flow velocity meter 36 are provided on the front surface side of the rack 3, and an exhaust temperature sensor 37 is provided on the rear surface side thereof. The intake temperature sensor 35 measures a temperature of the intake air F1 (intake temperature). The flow velocity meter 36 measures the velocity of the air F. The exhaust temperature sensor 37 measures a temperature of the exhaust air F2 (exhaust temperature). In the present embodiment, the flow velocity meter 36 is provided on the front surface side of the rack 3 and measures the velocity of the intake air F1. In other embodiments, the flow velocity meter 36 may be provided on the rear surface side of the rack 3 to measure the velocity of the exhaust air F2.

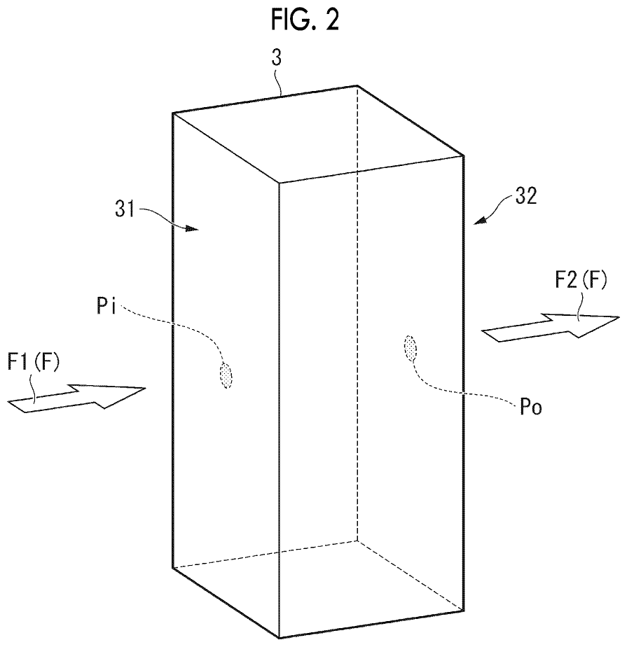

FIG. 2 is a diagram showing an example of an inlet measurement point and an outlet measurement point according to the first embodiment.

As shown in FIG. 2, an inlet measurement point Pi, which is a representative point for measuring the temperature and flow velocity of the intake air F1, is set at any location on the front surface 31 of the rack 3. Further, an outlet measurement point Po, which is a representative point for measuring the temperature of the exhaust air F2, is set at any location on the rear surface 32 of the rack 3. In the example of FIG. 2, the inlet measurement point Pi and the outlet measurement point Po are set near the center of the front surface 31 and the rear surface 32 of the rack 3, respectively, but the present invention is not limited thereto. In other embodiments, the positions of the inlet measurement point Pi and the outlet measurement point Po may be changed in accordance with the positions or the like of the air inlet and the air outlet. The intake temperature sensor 35 and the flow velocity meter 36 are provided near the inlet measurement point Pi. The exhaust temperature sensor 37 is provided near the outlet measurement point Po.

The air conditioner 4 cools air F within the data center DC. In the example of FIG. 1, the air conditioners 4 (4a to 4g) are provided one for each passage (the cold aisle CI, the hot aisle HI) present in the front-rear direction of the rack 3. It is assumed that each air conditioner 4 has the same configuration. The air conditioner 4 has an indoor unit 41 and an outdoor unit 42. The indoor unit 41 is installed inside the data center DC, and the outdoor unit 42 is installed outside the data center DC. The indoor unit 41 and the outdoor unit 42 are connected by a pipe 43 through which a refrigerant flows.

Also, the indoor unit 41 is provided with a suction temperature sensor 45. The suction temperature sensor 45 measures a suction temperature, which is a temperature of the air F taken in by the indoor unit 41. The outdoor unit 42 is provided with an outside air temperature sensor 46. The outside air temperature sensor 46 measures an outside air temperature, which is a temperature outside the data center DC. The outside air temperature sensor 46 may be installed near the outdoor unit 42 instead of being attached to the outdoor unit 42.

### (Functional Configuration of Monitoring Device)

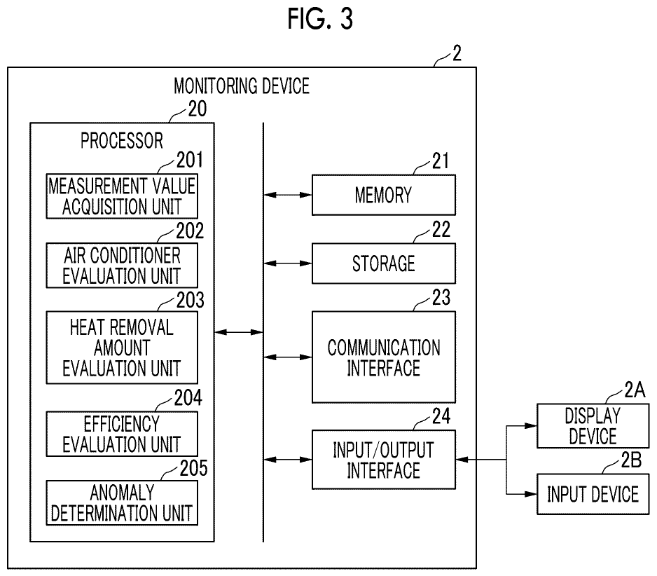

FIG. 3 is a block diagram showing a functional configuration of the monitoring device according to the first embodiment.

As shown in FIG. 3, the monitoring device 2 includes a processor 20, a memory 21, a storage 22, a communication interface 23, and an input/output interface 24.

The processor 20 operates in accordance with a predetermined program to cause the monitoring device 2 to perform various functions. The function of the processor 20 will be described later.

The memory 21 has a memory area necessary for the operations of the processor 20.

The storage 22 is a so-called auxiliary storage device, such as, for example, a hard disk drive (HDD) or a solid-state drive (SSD). Data that each unit of the processor 20 acquires, generates, and references during processing is stored in the storage 22.

The communication interface 23 is an interface for transmitting and receiving various types of data, control signals, and the like between the sensors provided in each rack 3 and the air conditioners 4.

The input/output interface 24 is a connection interface for communicating with devices such as a display device 2A and an input device 2B. The display device 2A is a monitor such as a liquid-crystal display. The input device 2B is a device such as a mouse or a keyboard for receiving input operations from an operator. The display device 2A and the input device 2B may be integrally configured by a touch panel, for example.

Next, a function of the processor 20 will be described. The processor 20 operates in accordance with a program prepared in advance to perform functions of a measurement value acquisition unit 201, an air conditioner evaluation unit 202, a heat removal amount evaluation unit 203, an efficiency evaluation unit 204, and an anomaly determination unit 205.

The measurement value acquisition unit 201 acquires measurement values of the intake temperature sensor 35, the flow velocity meter 36, and the exhaust temperature sensor 37 of each rack 3. Furthermore, the measurement value acquisition unit 201 acquires measurement values of the suction temperature sensor 45 and the outside air temperature sensor 46 of each air conditioner 4.

The air conditioner evaluation unit 202 evaluates air conditioner power of the air conditioner 4 based on the outside air temperature outside the data center DC and the suction temperature of the indoor unit 41 of the air conditioner 4. In the present embodiment, the air conditioner evaluation unit 202 evaluates the total power of a plurality of air conditioners 4.

The heat removal amount evaluation unit 203 evaluates a heat removal amount of the rack 3 based on the intake temperature, which is the temperature of air F (intake air F1) measured at the inlet measurement point Pi on the front surface 31 of the rack 3, the exhaust temperature, which is the temperature of air F (exhaust air F2) measured at the outlet measurement point Po on the rear surface 32 of the rack 3, and the flow velocity of air F (intake air F1 or exhaust air F2). In the present embodiment, the heat removal amount evaluation unit 203 evaluates the total heat removal amount of all the racks 3 in the data center DC.

The efficiency evaluation unit 204 evaluates the power usage effectiveness (PUE) of the air conditioners 4 in the data center DC based on the air conditioner power and the heat removal amount of the racks 3.

The anomaly determination unit 205 determines whether or not there is an anomaly in the power consumption of the air conditioner 4. Specifically, the anomaly determination unit 205 determines that the power consumption of the air conditioner 4 is anomalous when the PUE exceeds a predetermined determination threshold value.

### (Processing Flow of Monitoring Device)

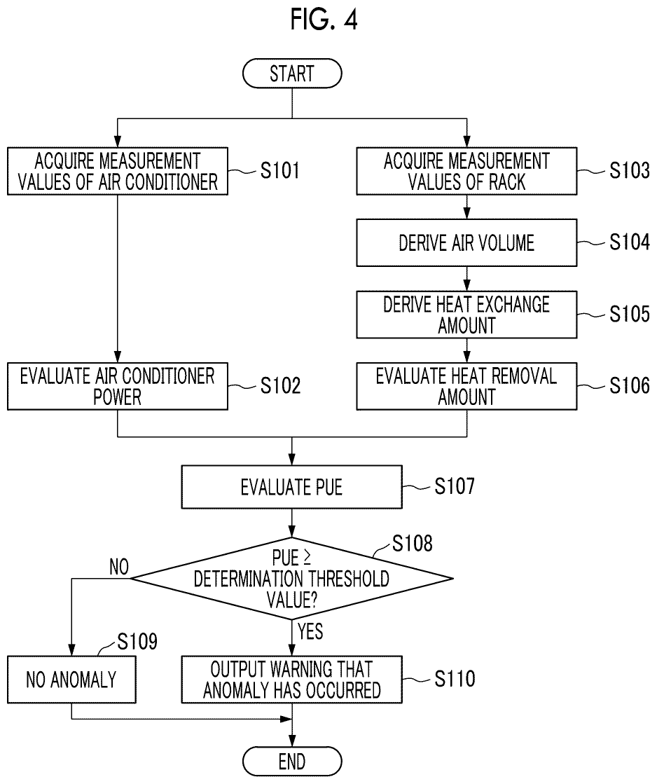

FIG. 4 is a flowchart showing an example of processing performed by the monitoring device according to the first embodiment.

Here, the flow of processing performed by the monitoring device 2 will be described with reference to FIG. 4.

First, the process in which the monitoring device 2 evaluates the air conditioner power will be described.

The measurement value acquisition unit 201 acquires the measurement values of the suction temperature and the outside air temperature from the suction temperature sensor 45 and the outside air temperature sensor 46 of each air conditioner 4 (step S101).

The air conditioner evaluation unit 202 evaluates the air conditioner power of the entire data center DC based on the suction temperature and the outside air temperature of the air conditioner 4 (step S102).

For example, the air conditioner evaluation unit 202 calculates the power (power consumption [KW]) of each air conditioner 4 based on the suction temperature and the outside air temperature of each air conditioner 4, the length (pipe distance) of the pipe 43 connecting the indoor unit 41 and the outdoor unit 42, and the cooling capacity specified in the specifications of the air conditioner 4. The method of calculating the power of each air conditioner 4 is known, and therefore the description will be omitted. Furthermore, the air conditioner evaluation unit 202 sums up the power of each air conditioner 4 to obtain a total air conditioner power value Qp [KW] for the entire data center DC. In the example of FIG. 1, the air conditioner evaluation unit 202 obtains a total air conditioner power value Qp, which is the sum of the powers of the eight air conditioners 4a to 4g.

Next, the process in which the monitoring device 2 evaluates the heat removal amount from the data center DC will be described. This process is carried out in parallel with the evaluation of air conditioner power.

The measurement value acquisition unit 201 acquires measurement values of the temperature of intake air F1 (intake temperature), the flow velocity of intake air F1, and the temperature of exhaust air F2 (exhaust temperature) from the intake temperature sensor 35, the flow velocity meter 36, and the exhaust temperature sensor 37 of each rack 3 (step S103).

Furthermore, the heat removal amount evaluation unit 203 evaluates a heat removal amount Qc of the rack 3 by the air conditioner 4 from each measurement value.

Specifically, first, the heat removal amount evaluation unit 203 derives an air volume (mass flow rate m [kg/s]) of the air F for each rack 3 using the following Equations (1) and (2) (step S104).

$$V = A \times v \qquad ( 1 )$$

$$m = V \times ρ \qquad ( 2 )$$

In Equation (1), V is a volume flow rate [m³/s], A is a cross-sectional area of the air inlet of the rack 3, and v is a flow velocity of the intake air F1 measured by the flow velocity meter 36. Furthermore, p in Equation (2) is a density of the intake air F1. The density p is obtained from the temperature (intake temperature) and the pressure (atmospheric pressure) of the intake air F1.

Next, the heat removal amount evaluation unit 203 derives a heat exchange amount Q [KW] of each rack 3 using the following Equation (3) (step S105).

$$Q = m \times cp \times Δ T \qquad ( 3 )$$

In Equation (3), m is a mass flow rate derived in Equation (2), cp is a specific heat, and ΔT is a temperature difference between the intake temperature and the exhaust temperature. The specific heat cp is obtained from the temperature (intake temperature) and the pressure (atmospheric pressure) of the intake air F1.

Next, the heat removal amount evaluation unit 203 sums up the respective heat exchange amounts Q of the plurality of racks 3, and evaluates the total heat removal amount Qc [KW] of all the racks 3 in the data center DC (step S106).

When the evaluation of the air conditioner power and the heat removal amount is completed, the efficiency evaluation unit 204 evaluates the PUE of the air conditioner 4 in the data center DC using the following Equation (4) (step S107).

$$PUE = ( Qp + Qc ) / Qc \qquad ( 4 )$$

Next, the anomaly determination unit 205 determines whether or not the power consumption of the air conditioner 4 is anomalous, based on the PUE calculated by Equation (4) (step S108). Specifically, when the PUE is less than a predetermined determination threshold value (step S108; NO), the anomaly determination unit 205 determines that there is no anomaly (step S109), and ends the process. The determination threshold value is, for example, “1.5” and may be changed as desired based on the required specifications for energy efficiency of the data center DC, the size of the data center DC, and the like.

On the other hand, when the PUE is equal to or greater than the determination threshold value (step S108; YES), the anomaly determination unit 205 determines that the power consumption of the air conditioner 4 is anomalous, and outputs a warning to the operator (step S110). The anomaly determination unit 205 outputs a warning in the form of a warning message to the display device 2A, for example. In addition, the anomaly determination unit 205 may read out a warning message or output a warning sound from a speaker (not shown), or may transmit a warning message (email or the like) to a terminal carried by the operator (a personal computer, a smartphone, a tablet, and the like).

The monitoring device 2 periodically executes a series of processes in FIG. 3 to monitor the PUE of the air conditioner 4 in the data center DC.

### (Operation and Effects)

As described above, the monitoring device 2 according to the present embodiment includes an air conditioner evaluation unit 202 that evaluates air conditioner power Qp based on the outside air temperature measured outside the data center DC and the suction temperature of the indoor unit 41 of the air conditioner 4, a heat removal amount evaluation unit 203 that evaluates the heat removal amount Qc of the rack 3 based on the intake temperature of the cooling air F taken into the rack 3, the exhaust temperature of the air F exhausted from the rack 3, and the flow velocity of the air F, and an efficiency evaluation unit 204 that evaluates the PUE of the air conditioner 4 of the data center DC based on the air conditioner power Qp and the heat removal amount Qc.

In this way, the monitoring device 2 can evaluate and monitor the efficiency (PUE) of the power consumed by the air conditioner 4 to cool the rack 3, simply by providing a simple configuration in the data center DC to measure the temperature and the flow velocity.

The monitoring device 2 further includes an anomaly determination unit 205 that determines that the power consumption of the air conditioner 4 is anomalous when the PUE exceeds a predetermined determination threshold value.

In this way, the monitoring device 2 can detect that the air conditioner 4 in the data center DC is anomalously consuming power that is not contributing to cooling the rack 3.

Furthermore, when it is determined that the power consumption of the air conditioner 4 is anomalous, the anomaly determination unit 205 may output a warning to an operator.

By outputting a warning, the monitoring device 2 can prompt the operator to quickly take measures, such as changing the settings of the air conditioner.

### Second Embodiment

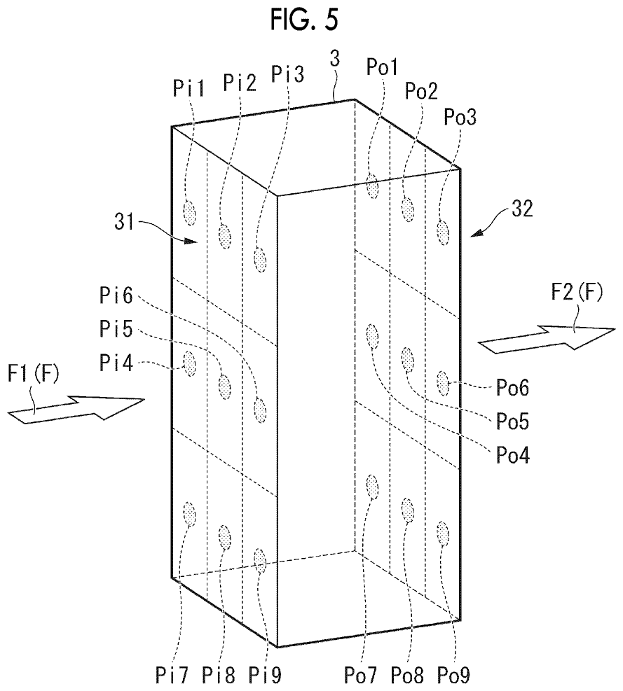

Next, a second embodiment will be described with reference to FIG. 5. Components common to the above-described embodiment are designated by the same reference numerals and detailed description thereof will be omitted.

FIG. 5 is a diagram showing an example of an inlet measurement point and an outlet measurement point according to the second embodiment.

As shown in FIG. 5, the inlet measurement points Pi for measuring the intake temperature and the flow velocity of the rack 3 and the outlet measurement points Po for measuring the exhaust temperature may each be set at a plurality of locations.

In the example of FIG. 5, the front surface 31 of the rack 3 is divided into nine regions, and one inlet measurement point Pi1 to Pi9 (for example, near the center of each region) is set in each region. Furthermore, the rear surface 32 of the rack 3 is divided into nine regions corresponding to the front surface 31. In each region of the rear surface 32, outlet measurement points Po1 to Po9 are set at positions corresponding to the inlet measurement points Pi1 to Pi9, respectively.

The intake temperature sensor 35 and the flow velocity meter 36 are provided at each of the inlet measurement points Pi1 to Pi9. The exhaust temperature sensor 37 is provided at each of the outlet measurement points Po1 to Po9.

In the present embodiment, the heat removal amount evaluation unit 203 of the monitoring device 2 obtains the air volume (mass flow rate m) for each region of the rack 3 using the measurement values at each measurement point in step S104 of FIG. 4.

Specifically, the heat removal amount evaluation unit 203 first obtains a volume flow rate Vi (V1 to V9) for each region of the rack 3 based on a flow velocity vi (v1 to v9) measured at each of the inlet measurement points Pi1 to Pi9 and a cross-sectional area Ai (A1 to A9) of the air inlet in the region corresponding to each of the inlet measurement points Pi1 to Pi9, using the following Equation (5).

$$Vi = Ai \times vi \qquad ( 5 )$$

In addition, the heat removal amount evaluation unit 203 obtains a mass flow rate mi (m1 to m9) of each region of the rack 3 based on the volume flow rate Vi (V1 to V9) and the density ρi (ρ1 to ρ9) of each region using the following Equation (6).

$$mi = Vi \times ρi \qquad ( 6 )$$

Next, in step S105 of FIG. 4, the heat removal amount evaluation unit 203 obtains the heat exchange amount Q of the rack 3 using the measurement values at each measurement point. Specifically, the heat removal amount evaluation unit 203 obtains the heat exchange amount Q, which is the sum of the amounts of heat exchanged for each region of the rack 3, based on the mass flow rate mi (m1 to m9) of each measurement point, a specific heat cpi (cp1 to cp9), and a temperature difference ΔTi (ΔT1 to ΔT9) between the intake temperature and the exhaust temperature, using the following Equation (7).

$$Q = \sum ( mi \times cpi \times Δ Ti ) \qquad ( 7 )$$

Furthermore, in step S106 of FIG. 4, the heat removal amount evaluation unit 203 sums up the respective heat exchange amounts Q of the plurality of racks 3, and evaluates the total heat removal amount Qc [KW] of all the racks 3 in the data center DC.

As described above, in the monitoring device 2 according to the present embodiment, the heat removal amount evaluation unit 203 calculates the heat exchange amount Q, which is the sum of the heat exchange amounts for each region corresponding to each measurement point, based on the measurement values measured at each of the plurality of inlet measurement points Pi and outlet measurement points Po of the rack 3, and evaluates the heat exchange amount Q for each of the plurality of racks 3. Furthermore, the heat removal amount evaluation unit 203 sums up the heat exchange amounts Q of each of the plurality of racks 3 to evaluate the heat removal amount Qc of all the plurality of racks 3.

In this way, the monitoring device 2 can more accurately evaluate the heat removal amount Qc from the rack 3 and the efficiency (PUE) of the power consumed by the air conditioner 4 in cooling the rack 3.

### Third Embodiment

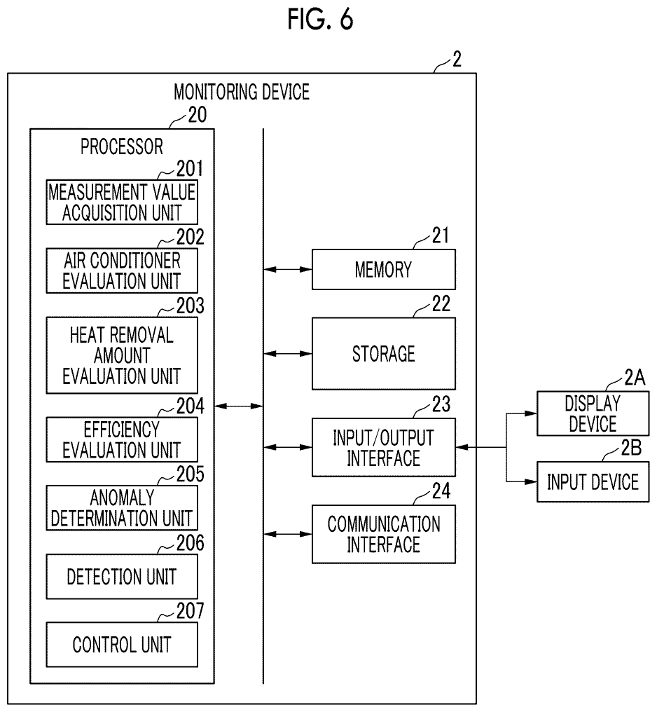

Next, a third embodiment will be described with reference to FIGS. 6 to 8. Components common to the above-described embodiment are designated by the same reference numerals and detailed description thereof will be omitted.

### (Functional Configuration of Monitoring Device)

FIG. 6 is a diagram showing a configuration of an air conditioner and a rack according to the third embodiment.

As shown in FIG. 6, in the monitoring device 2 according to the present embodiment, the processor 20 further performs functions of a detection unit 206 and a control unit 207.

When the anomaly determination unit 205 determines that the power consumption of the air conditioner 4 is anomalous, the detection unit 206 detects, among the plurality of racks 3, a rack 3 having a hot spot where the intake temperature or the exhaust temperature is equal to or higher than a predetermined upper limit temperature. The hot spot is a location in the data center DC where the temperature is locally high. Hot spots may occur in racks 3 that store more servers than other racks 3, racks 3 that store servers with concentrated computational loads, racks 3 that are installed at positions away from air conditioners 4, or the like.

When the detection unit 206 detects a rack having a hot spot, the control unit 207 lowers the set temperature of the air conditioner 4 that contributes most to cooling the rack 3 having the hot spot, among the plurality of air conditioners 4, and raises the set temperature of at least one of the other air conditioners 4.

### (Processing Flow of Monitoring Device)

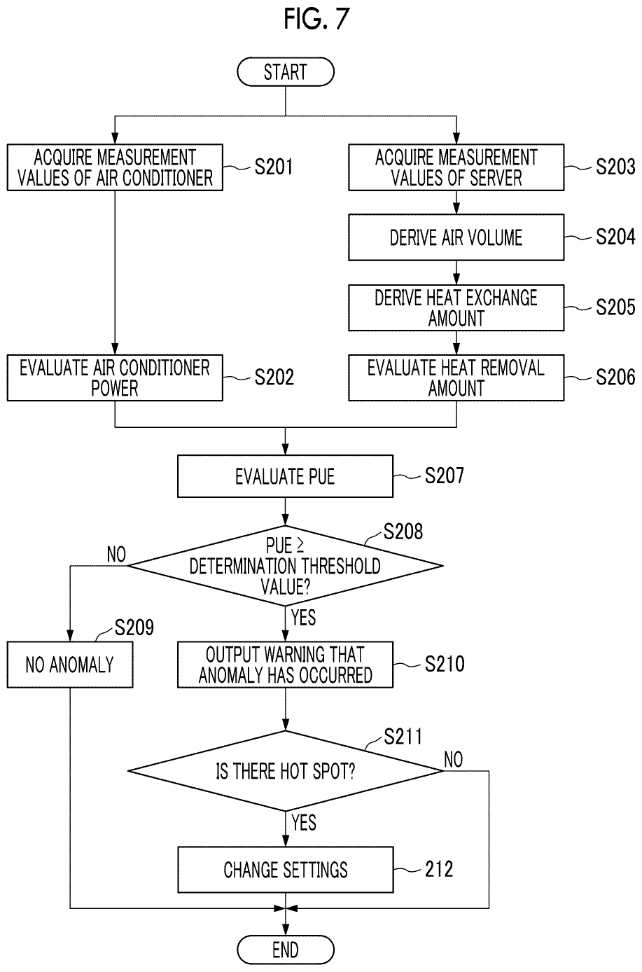

FIG. 7 is a flowchart showing an example of processing performed by the monitoring device according to the third embodiment.

The processes in steps S201 to S210 in FIG. 7 are the same as the processes in steps S101 to S110 in FIG. 4, and therefore description thereof will be omitted. Here, the processes specific to the present embodiment, that is, the processes of steps S211 to S212 in FIG. 7, will be described.

When the anomaly determination unit 205 determines that the power consumption of the air conditioner 4 is anomalous (S208; YES, and S210 is performed), the detection unit 206 determines whether or not there is a hot spot (step S211).

When the intake temperatures and exhaust temperatures of all the racks 3 are lower than the predetermined upper limit temperatures, the detection unit 206 determines that no hot spot is present in the data center DC (step S211; NO). This determination result may be displayed on the display device 2A such that the operator can check the result.

On the other hand, when the intake temperature or exhaust temperature in any of the racks 3 is equal to or higher than the upper limit temperature, the detection unit 206 determines that a hot spot is present in the rack 3 where this temperature was measured (step S211; YES).

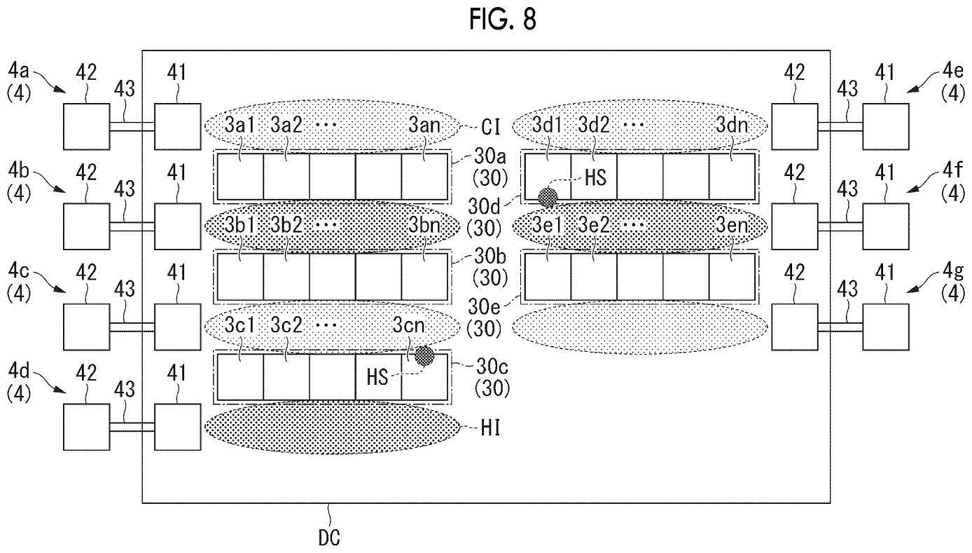

FIG. 8 is a diagram for describing functions of the monitoring device according to the third embodiment.

For example, it is assumed that, among a plurality of rack rows 30a to 30e, the intake temperature of a rack 3cn in the rack row 30c and the exhaust temperature of a rack 3d1 in the rack row 30d are equal to or higher than the upper limit temperature. In this case, the detection unit 206 detects a rack 3cn and a rack 3d1 as racks having hot spots.

At this time, the detection unit 206 may display information capable of specifying the position where the hot spot is present (such as the name or identification number of the rack 3cn and 3d1 in which the hot spot is present) on the display device 2A to notify the operator. In addition, a mark indicating the position of the rack 3cn or 3d1 in which a hot spot was detected (hot spot mark HS in FIG. 8) may be superimposed on image data (map data) showing the disposition of each rack 3 in the data center DC and displayed on the display device 2A.

In addition, when a plurality of inlet measurement points Pi and outlet measurement points Po are set on each rack 3 as in the second embodiment, the detection unit 206 may notify the operator of the position of the measurement point where the hot spot is present via the display device 2A.

Next, the control unit 207 performs a setting change process of lowering the set temperature of the air conditioner 4 that contributes most to cooling the rack 3 having the hot spot, among the plurality of air conditioners 4 (4a to 4e), and raising the set temperature of at least one of the other air conditioners 4 (step S212).

In the example of FIG. 8, the rack 3en has a hot spot on the front surface 31 (air inlet) side. Therefore, the control unit 207 selects the air conditioner 4c that cools the passage in which this hot spot is present (the cold aisle CI between the rack rows 30b and 30c) as the air conditioner that will contribute most to cooling the rack 3bn. Furthermore, the rack 3d1 has a hot spot on the rear surface 32 (air outlet) side. Therefore, the control unit 207 selects the air conditioner 4e that cools the passage in which this hot spot is present (the hot aisle HI between the rack rows 30d and 30e) as the air conditioner that will contribute most to cooling the rack 3d1.

The control unit 207 lowers the set temperatures of the selected air conditioners 4c and 4e by a certain temperature (α° C.). Furthermore, for the air conditioners for which the set temperature may be raised among the other air conditioners 4a, 4b, 4d, 4f, and 4g, the set temperature is raised by a certain temperature (β° C.). The values of α° C. and β° C. may be the same as or different from each other.

The control unit 207 sets a reference intake temperature and a reference exhaust temperature in advance, for example. When the intake temperatures of all the racks 3 with their front surfaces 31 facing a certain passage are equal to or lower than the reference intake temperature, the control unit 207 determines that the set temperature of the air conditioner 4 that cools this passage may be raised. In FIG. 8, it is assumed that the intake temperatures of all racks 3a1 to 3an in the rack row 30a are equal to or lower than the reference intake temperature. In this case, the control unit 207 determines that the set temperature of the air conditioner 4a that cools the passage on the intake side of this rack row 30a may be raised.

The control unit 207 may select a plurality of air conditioners 4 for which the set temperature may be raised. For example, when the exhaust temperatures of all racks 3a1 to 3an in the rack row 30a and the exhaust temperatures of all racks 3b1 to 3bn in the rack row 30b are equal to or lower than the reference exhaust temperature, the control unit 207 determines that the set temperature of the air conditioner 4b that cools the passage between these rack rows 30a and 30b may be raised. In response to this, the control unit 207 performs control to raise the set temperature by β° C. for both the air conditioner 4a and the air conditioner 4b.

In this way, the monitoring device 2 can suppress an increase in the overall power consumption of the air conditioners 4 and deterioration of the PUE while improving the cooling effect in locations where hot spots are present.

The monitoring device 2 periodically executes the series of processes in FIG. 6 to monitor the PUE of the air conditioner 4 in the data center DC, as well as to detect and eliminate hot spots.

In other embodiments, the monitoring device 2 may execute the process of notifying the operator of the presence of a hot spot, and cause the operator to manually change the temperature setting of the air conditioner 4. In this case, the monitoring device 2 may not have a control unit 207.

### (Operation and Effects)

As described above, the monitoring device 2 according to the present embodiment further includes a detection unit 206 that detects, when it is determined that the power consumption of the air conditioner 4 is anomalous, a rack, among the plurality of racks 3, in which a hot spot is present where the intake temperature or the exhaust temperature is equal to or higher than a predetermined upper limit temperature.

In this way, the monitoring device 2 can quickly detect the presence of a hot spot and specify the position of the hot spot. Furthermore, the monitoring device 2 may display information capable of specifying the position of this hot spot on the display device 2A. In this way, the operator can check the position of the hot spot and change the set temperature of each air conditioner 4 as desired.

In addition, the monitoring device 2 further includes a control unit 207 that, when a hot spot is detected, lowers the set temperature of the air conditioner 4 that contributes most to cooling the rack 3 having the hot spot, among the plurality of air conditioners 4, and raises the set temperatures of the other air conditioners 4.

In the related art, when a hot spot is present in a data center, the hot spot is eliminated by lowering the set temperatures of all air conditioners. However, lowering set temperatures of all air conditioners in this way increases the PUE. However, the monitoring device 2 according to the present embodiment performs control to lower only the set temperature of the air conditioner 4 that contributes to cooling the hot spot, and to raise the set temperatures of the other air conditioners. In this way, the monitoring device 2 can suppress an increase in the overall power consumption of the air conditioners 4 and deterioration of the PUE while improving the cooling effect in locations where hot spots are present.

### OTHER EMBODIMENTS

Although one embodiment has been described in detail above with reference to the drawings, the specific configuration is not limited to the above, and various design modifications and the like can be made. That is, in other embodiments, the order of the above-mentioned processes may be changed as appropriate. Furthermore, some of the processing may be executed in parallel.

In the above-described embodiment, an example has been described in which the data center DC is configured with only one floor, but in other embodiments, the data center DC may have a plurality of floors. In this case, the efficiency evaluation unit 204 of the monitoring device 2 may evaluate power usage effectiveness pPUE (partial PUE) of the air conditioner 4 for each floor. Furthermore, the efficiency evaluation unit 204 may further evaluate the PUE of the air conditioners 4 in the entire data center DC by summing up the pPUE of the air conditioners 4 for each floor.

### <Supplementary Notes>

The monitoring device, the monitoring method, and the program described in the above-described embodiments can be understood, for example, as follows.

(1) According to a first aspect, a monitoring device 2 includes: an air conditioner evaluation unit 202 that evaluates air conditioner power Qp of an air conditioner 4 including an outdoor unit 42 installed outside a data center DC and an indoor unit 41 installed inside the data center DC based on an outside air temperature measured outside the data center DC and a suction temperature of the indoor unit 41; a heat removal amount evaluation unit 203 that evaluates a heat removal amount Qc of a rack 3 storing at least one electronic device in the data center DC based on an intake temperature obtained by measuring a temperature of air F taken into the rack 3, an exhaust temperature obtained by measuring a temperature of the air F exhausted from the rack 3, and a flow velocity of the air F; and an efficiency evaluation unit 204 that evaluates power usage effectiveness (PUE) of the air conditioner 4 in the data center DC based on the air conditioner power Qp and the heat removal amount Qc.

In this way, the monitoring device 2 can evaluate and monitor the efficiency (PUE) of the power consumed by the air conditioner 4 to cool the rack 3, simply by providing a simple configuration in the data center DC to measure the temperature and the flow velocity.

(2) According to a second aspect, in the monitoring device 2 according to the first aspect, the intake temperature is measured at a plurality of inlet measurement points Pi set on a front surface 31 of the rack 3, the exhaust temperature is measured at a plurality of outlet measurement points Po set on a rear surface 32 of the rack 3 corresponding to each of the plurality of inlet measurement points Pi, the flow velocity is measured at the plurality of inlet measurement points Pi or the plurality of outlet measurement points Po, and the heat removal amount evaluation unit 203 evaluates the heat removal amount Qc of the rack 3 based on a plurality of the intake temperatures, a plurality of the exhaust temperatures, and a plurality of the flow velocities.

In this way, the monitoring device 2 can more accurately evaluate the heat removal amount Qc from the rack 3 and the efficiency (PUE) of the power consumed by the air conditioner 4 in cooling the rack 3.

(3) According to a third aspect, the monitoring device 2 according to the first or second aspect further includes an anomaly determination unit 205 that determines that power consumption of the air conditioner 4 is anomalous when the power usage effectiveness (PUE) exceeds a predetermined determination threshold value.

In this way, the monitoring device 2 can detect that the air conditioner 4 in the data center DC is anomalously consuming power that is not contributing to cooling the rack 3.

(4) According to a fourth aspect, the monitoring device 2 according to the third aspect further includes a detection unit 206 that, when it is determined that the power consumption of the air conditioner 4 is anomalous, detects a rack 3, among a plurality of the racks 3, in which a hot spot is present where the intake temperature or the exhaust temperature is equal to or higher than a predetermined upper limit temperature.

In this way, the monitoring device 2 can quickly detect the presence of a hot spot and specify the position of the hot spot. Furthermore, the monitoring device 2 may display information capable of specifying the position of this hot spot on the display device 2A. In this way, the operator can check the position of the hot spot and change the set temperature of each air conditioner 4 as desired.

(5) According to a fifth aspect, the monitoring device 2 according to the fourth aspect further includes a control unit 207 that, when the hot spot is detected, lowers a set temperature of an air conditioner 4 that contributes most to cooling the rack 3 having the hot spot, among a plurality of the air conditioners 4, and raises a set temperature of at least one of the other air conditioners 4.

In this way, the monitoring device 2 can suppress an increase in the overall power consumption of the air conditioners 4 and deterioration of the PUE while improving the cooling effect in locations where hot spots are present.

(6) According to a sixth aspect, a monitoring method includes: a step of evaluating air conditioner power Qp of an air conditioner 4 including an outdoor unit 42 installed outside a data center DC and an indoor unit 41 installed inside the data center DC based on an outside air temperature measured outside the data center DC and a suction temperature of the indoor unit 41; a step of evaluating a heat removal amount Qc of a rack 3 storing at least one electronic device in the data center DC based on an intake temperature obtained by measuring a temperature of air F taken into the rack 3, an exhaust temperature obtained by measuring a temperature of the air F exhausted from the rack 3, and a flow velocity of the air F; and a step of evaluating power usage effectiveness (PUE) of the air conditioner 4 in the data center DC based on the air conditioner power Qp and the heat removal amount Qc.

(7) According to a seventh aspect, a program causes a monitoring device 2 to execute: a step of evaluating air conditioner power Qp of an air conditioner 4 including an outdoor unit 42 installed outside a data center DC and an indoor unit 41 installed inside the data center DC based on an outside air temperature measured outside the data center DC and a suction temperature of the indoor unit 41; a step of evaluating a heat removal amount Qc of a rack 3 storing at least one electronic device in the data center DC based on an intake temperature obtained by measuring a temperature of air F taken into the rack 3, an exhaust temperature obtained by measuring a temperature of the air F exhausted from the rack 3, and a flow velocity of the air F; and a step of evaluating power usage effectiveness (PUE) of the air conditioner 4 in the data center DC based on the air conditioner power Qp and the heat removal amount Qc.

### INDUSTRIAL APPLICABILITY

According to the above aspects, the power usage effectiveness (PUE) of the air conditioner in the data center can be monitored.

### REFERENCE SIGNS LIST

1: monitoring system
2: monitoring device
20: processor
201: measurement value acquisition unit
202: air conditioner evaluation unit
203: heat removal amount evaluation unit
204: efficiency evaluation unit
205: anomaly determination unit
206: detection unit
207: control unit
21: memory
22: storage
23: communication interface
24: input/output interface
2A: display device
2B: input device
3: rack
30: rack row
31: front surface
32: rear surface
35: intake temperature sensor
36: flow velocity meter
37: exhaust temperature sensor
4: air conditioner
41: indoor unit
42: outdoor unit
43: pipe
45: suction temperature sensor
46: outside air temperature sensor

1. A monitoring device comprising:
an air conditioner evaluation unit that evaluates air conditioner power of an air conditioner including an outdoor unit installed outside a data center and an indoor unit installed inside the data center based on an outside air temperature measured outside the data center and a suction temperature of the indoor unit;
a heat removal amount evaluation unit that evaluates a heat removal amount of a rack storing at least one electronic device in the data center based on an intake temperature obtained by measuring a temperature of air taken into the rack, an exhaust temperature obtained by measuring a temperature of the air exhausted from the rack, and a flow velocity of the air; and
an efficiency evaluation unit that evaluates power usage effectiveness of the air conditioner in the data center based on the air conditioner power and the heat removal amount.

2. The monitoring device according to claim 1,
wherein the intake temperature is measured at a plurality of inlet measurement points set on a front surface of the rack,
the exhaust temperature is measured at a plurality of outlet measurement points set on a rear surface of the rack corresponding to each of the plurality of inlet measurement points,
the flow velocity is measured at the plurality of inlet measurement points or the plurality of outlet measurement points, and
the heat removal amount evaluation unit evaluates the heat removal amount of the rack based on a plurality of the intake temperatures, a plurality of the exhaust temperatures, and a plurality of the flow velocities.

3. The monitoring device according to claim 1, further comprising
an anomaly determination unit that determines that power consumption of the air conditioner is anomalous when the power usage effectiveness exceeds a predetermined determination threshold value.

4. The monitoring device according to claim 3, further comprising
a detection unit that, when it is determined that the power consumption of the air conditioner is anomalous, detects a rack, among a plurality of the racks, in which a hot spot is present where the intake temperature or the exhaust temperature is equal to or higher than a predetermined upper limit temperature.

5. The monitoring device according to claim 4, further comprising
a control unit that, when the hot spot is detected, lowers a set temperature of an air conditioner that contributes most to cooling the rack having the hot spot, among a plurality of the air conditioners, and raises a set temperature of at least one of the other air conditioners.

6. A monitoring method comprising:
a step of evaluating air conditioner power of an air conditioner including an outdoor unit installed outside a data center and an indoor unit installed inside the data center based on an outside air temperature measured outside the data center and a suction temperature of the indoor unit;
a step of evaluating a heat removal amount of a rack storing at least one electronic device in the data center based on an intake temperature obtained by measuring a temperature of air taken into the rack, an exhaust temperature obtained by measuring a temperature of the air exhausted from the rack, and a flow velocity of the air; and
a step of evaluating power usage effectiveness of the air conditioner in the data center based on the air conditioner power and the heat removal amount.

7. A non-transitory computer-readable medium that stores a program causing a monitoring device to execute:
a step of evaluating air conditioner power of an air conditioner including an outdoor unit installed outside a data center and an indoor unit installed inside the data center based on an outside air temperature measured outside the data center and a suction temperature of the indoor unit;
a step of evaluating a heat removal amount of a rack storing at least one electronic device in the data center based on an intake temperature obtained by measuring a temperature of air taken into the rack, an exhaust temperature obtained by measuring a temperature of the air exhausted from the rack, and a flow velocity of the air; and
a step of evaluating power usage effectiveness of the air conditioner in the data center based on the air conditioner power and the heat removal amount.
